(19) United States
(12) Patent Application Publication
(10) Pub. No.: US 2012/0167962 A1
(43) Pub. Date: Jul. 5, 2012

(54) SYSTEM AND METHOD FOR GENERATING A BEAM OF PARTICLES

(75) Inventors: Uzi Even, Tel-Aviv (IL); Nachum Lavie, Tel-Aviv (IL); Fernando Patolsky, Rechovot (IL)

(73) Assignee: RAMOT AT TEL-AVIV UNIVERSITY LTD., TEL-AVIV (IL)

(21) Appl. No.: 13/395,445

(22) PCT Filed: Jun. 30, 2010
(86) PCT No.: PCT/IL10/00528

§ 371 Date: Mar. 11, 2012

Related U.S. Application Data
(60) Provisional application No. 61/272,322, filed on Sep. 11, 2009.

(51) Int. Cl. H01J 27/02; B32B 15/00; B32B 3/10; H01L 31/02; C23C 14/48; C22C 5/04

(52) U.S. Cl. 136/252; 315/111.81; 427/595; 420/462; 428/209

(57) ABSTRACT

A method of fabricating a film. The method comprises directing onto a substrate a pulsed supersonic beam of a molecular precursor characterized by kinetic energy of at least 1 eV per molecule, such that non-volatile species of molecules of the precursor are deposited on the substrate.

### RELATED APPLICATION

This application claims the benefit of priority from U.S. Application No. 61/272,322, the contents of which are hereby incorporated by reference as if fully set forth herein.

### FIELD AND BACKGROUND OF THE INVENTION

The present invention, in some embodiments thereof, relates to particles beams and, more particularly, but not exclusively, to a system and method for generating a beam of molecules, atoms or ions. In some embodiments of the present invention the generated beam is used for fabricating a film, e.g., a thin film.

### Supersonic Jets

Supersonic jets have been used successfully to generate beams of isolated molecules over the past two decades. Conventionally, such jets are generated by means of continuous nozzles or pulsed valves at ambient or elevated temperatures. Large and relatively heavy molecules are first accelerated to a velocity of a relatively light carrier gas, and the internal modes energy of the molecules (vibrations and rotation) is then carried away by soft collisions in the jet, thereby cooling the molecules to low a temperature.

### Gas Discharge

For many years, electrical discharge in supersonic beams has been used to generate ions, meta-stable atoms and dissociated neutral radicals. Known electrical discharge systems employ various types of excitation sources. In most cases the electrode material is sputtered leading to short life time of the source, and contamination of the emergent beam. The hot gas created in the discharge produces beams with low Mach number and high speeds. Also known is a discharge mechanism known as Dielectric Barrier Discharge (DBD) in which a dielectric barrier is placed between electrodes. The dielectric barrier serves to separate the electrode from the plasma and is required to partially inhibit the direct flow of current between the two electrodes and distribute the discharge uniformly over the electrodes.

### Thin Film Deposition

Advances in modern semiconductor device technology have allowed increasing numbers of devices and circuits to be fabricated within a single semiconductor chip. This has required increasing microminiaturization of the interconnection metallurgy system connecting the elements within the chip into circuits. Such miniaturization results in decreased costs and improved performance in integrated circuits but is constantly crowding the fabrication technology, particularly the photolithographic and etching techniques of the interconnection metallurgy.

In integrated circuit design, for example, millions of impurity regions are conventionally fabricated in a silicon chip, approximately 125-200 mils square. Such regions form transistors, diodes, resistors and the like which are then connected together by thin film wiring patterns atop the chip to form various circuits and for connection to input-output terminals. This interconnection thin film system atop the chip is extremely complex and usually employs two or three separate levels of complex conductive patterns, each separated by one or more layers of dielectric material.

Thin films are also employed in the field of optics, wherein multilayer thin film structures and coatings are used for controlling reflectance, transmittance and absorbance of light. Representative examples include, thin film multilayer coatings that are infrared (IR) reflective and radiofrequency (RF) transparent, signature control films that are reflective only in particular bands of the infrared and are otherwise transmissive or absorptive, coatings for modifying the spectral emittance of a surface by changing its reflectance and absorbance, and dichromatic color-shift coating compositions.

Conventionally, thin films and thin film patterns are fabricated by etching in the presence of etch-resistant photoresist layers. The process involves the traditional photolithographic wet-etching of both the thin film as well as the photoresist layers. Also known are thin film fabrication techniques which involve chemical vapor deposition (CVD), wherein a substrate is exposed to a volatile precursor that reacts or being decomposed on the surface of the substrate thus producing the film.

### SUMMARY OF THE INVENTION

According to an aspect of some embodiments of the present invention there is provided a method of fabricating a film. The method comprises directing onto a substrate a pulsed supersonic beam of a molecular precursor characterized by kinetic energy of at least 1 eV per molecule, such that non-volatile species of molecules of the precursor are deposited on the substrate. According to some embodiments of the invention the beam is characterized by a pulse duration of less than 50 microseconds.

According to some embodiments of the invention the non-volatile species comprise collision products being produced when the molecules collide with the substrate.

According to some embodiments of the invention the method comprises exposing the molecules to a discharge prior to the deposition, wherein the non-volatile species comprise dissociation products being produced during the discharge. According to some embodiments of the invention the discharge is by a dielectric barrier discharge system.

According to some embodiments of the invention the non-volatile species are deposited at a rate of less than 50 atoms in height per pulse.

According to some embodiments of the invention the beam is characterized by a divergence angle of less than 20°.

According to some embodiments of the invention the beam is characterized by a pulse rate of at least 30 Hz.

According to some embodiments of the invention the method comprises using a digital controller for controlling a number of pulses in the pulsed supersonic beam.

According to some embodiments of the invention the substrate is at a temperature of less than 140° C.

According to some embodiments of the invention precursor comprises a metal selected from the group consisting of iridium, ruthenium, rhenium, osmium, rhodium, platinum and gold.

According to some embodiments of the invention the precursor comprises a metal carbonyl.

According to some embodiments of the invention the precursor comprises ruthenium carbonyl.

According to some embodiments of the invention the beam comprises gas carrier which comprises at least one of helium, neon and argon.

According to an aspect of some embodiments of the present invention there is provided a film fabricated by a method as described above and/or further exemplified hereinunder.

According to an aspect of some embodiments of the present invention there is provided a reflective optical element which comprises a film fabricated by a method as described above and/or further exemplified hereinunder.

According to an aspect of some embodiments of the present invention there is provided a solar cell which comprises a film fabricated by a method as described above and/or further exemplified hereinunder.

According to an aspect of some embodiments of the present invention there is provided a transmissive optical element which comprises a film fabricated by a method as described above and/or further exemplified hereinunder.

According to an aspect of some embodiments of the present invention there is provided a birefringent optical element which comprises a film fabricated by a method as described above and/or further exemplified hereinunder.

According to an aspect of some embodiments of the present invention there is provided a polarizing optical element which comprises a film fabricated by a method as described above and/or further exemplified hereinunder.

According to an aspect of some embodiments of the present invention there is provided a semiconductor device which comprises a film fabricated by a method as described above and/or further exemplified hereinunder.

According to an aspect of some embodiments of the present invention there is provided a electronic circuitry which comprises a film fabricated by a method as described above and/or further exemplified hereinunder.

According to an aspect of some embodiments of the present invention there is provided a thin film transistor array which comprises a film fabricated by a method as described above and/or further exemplified hereinunder.

According to an aspect of some embodiments of the present invention there is provided a method of generating a beam of atoms or ions. The method comprises generating a pulsed beam which comprises a supersonic gas carrier mixed with a molecular precursor; and exposing the beam to a discharge so as to dissociate molecules of the precursor into ions or atoms.

According to some embodiments of the invention the beam is characterized by a pulse duration of less than 50 microseconds and kinetic energy of at least 1 eV per molecule.

According to some embodiments of the invention the discharge is by a dielectric barrier discharge system.

According to an aspect of some embodiments of the present invention there is provided a system for generating a beam of atoms or ions. The system comprises: a pulsed valve system for generating a pulsed beam which comprises a supersonic gas carrier mixed with a molecular precursor; and a gas discharge system mounted on the pulsed valve system for receiving and discharging the beam to dissociate molecules of the precursor into ions or atoms.

According to some embodiments of the invention the pulsed valve system is configured to generate a beam characterized by a pulse duration of less than 50 microseconds and kinetic energy of at least 1 eV per molecule.

According to some embodiments of the invention the gas discharge system comprises a dielectric barrier discharge system.

According to some embodiments of the invention the beam comprises less than 50 molecular layers per pulse.

According to some embodiments of the invention the beam is characterized by a divergence angle of less than 20°.

According to some embodiments of the invention the beam is characterized by a pulse rate of at least 30 Hz.

According to some embodiments of the invention the system comprises a digital controller for controlling a number of pulses in the pulsed supersonic beam.

According to some embodiments of the invention at least one of a pulse duration, a pulse rate, an amount of molecules per pulse, and a velocity profile of the molecules is selected such that a characteristic temperature of the atoms or ions is at most 1K.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a flowchart diagram of a method suitable for fabricating a film, according to some embodiments of the present invention;

FIG. 2 is a schematic illustration of a system suitable for fabricating a film, according to some embodiments of the present invention;

FIG. 3 is a schematic illustration of a method suitable for generating a beam of atoms or ions, according to some embodiments of the present invention;

FIGS. 4A and 4B are schematic illustrations showing a perspective view (FIG. 4A) and a cross sectional view (FIG. 4B) of a pulsed valve system, according to some embodiments of the present invention;

FIG. 5 shows simulation results of the generated magnetic field for a 36 turn coil;

FIGS. 6A-C show temperature maps of a cone nozzle (FIG. 6A), a trumpet nozzle (FIG. 6B) and a bell-shape (Lavalle) nozzle (FIG. 6C);

FIG. 7 is a schematic illustration showing an exploded view of dielectric barrier discharge system, according to some embodiments of the present invention;

FIG. 8 is a schematic illustration of a electrical driver scheme for discharging a beam of a molecular precursor, according to various exemplary embodiments of the present invention;

FIG. 9 shows a characteristic pulsed valve opening as a function of time for a pulsed valve system according to some embodiments of the present invention;

FIGS. 10A-C are images showing layers of ruthenium deposited according to some embodiments of the present invention;

FIG. 11 shows rf burst and light emitted as measured during a discharge experiment performed according to some embodiments of the present invention;

FIG. 12 is an image showing a head on view of a DBD discharge system of some embodiments of the invention during its operation;

FIG. 13 shows a meta-stable caused current as measured in experiments performed according to some embodiments of the present invention; and

FIGS. 14A and 14B show positive and negative ion currents as measured in experiments performed according to some embodiments of the present invention.

### DESCRIPTION OF SPECIFIC EMBODIMENTS OF THE INVENTION

The present invention, in some embodiments thereof, relates to particles beams and, more particularly, but not exclusively, to a system and method for generating a beam of molecules, atoms or ions. In some embodiments of the present invention the generated beam is used for fabricating a film, e.g., a thin film.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

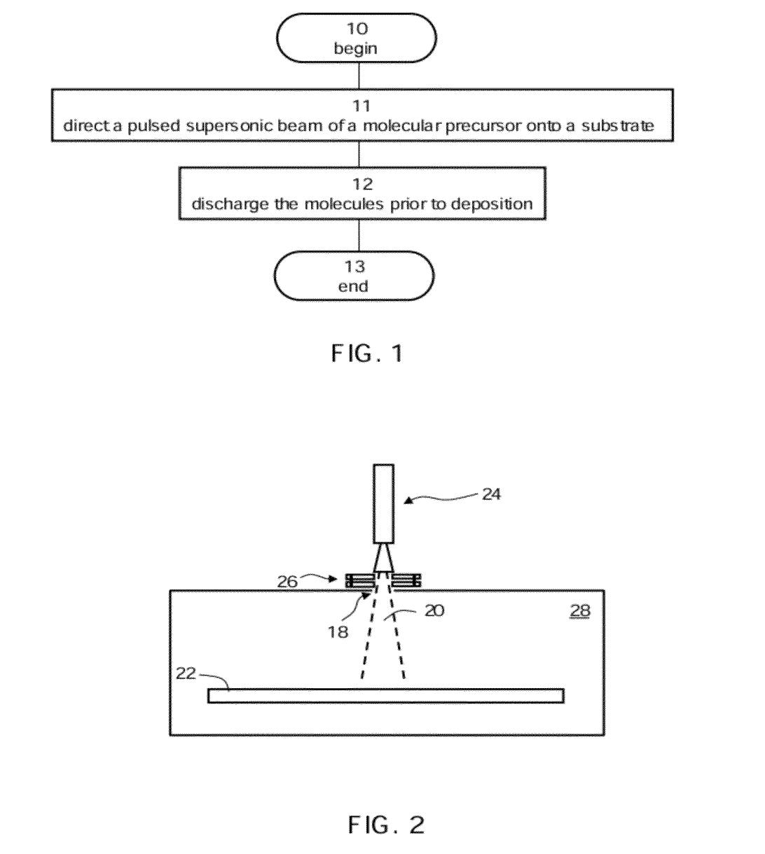

Referring now to the drawings, FIG. 1 is a flowchart diagram and FIG. 2 is a schematic illustration of a method suitable for fabricating a film, e.g., a thin film, according to various exemplary embodiments of the present invention. It is to be understood that several operations described below are optional and may not be executed.

The method begins at 10 and continues to 11 at which a pulsed supersonic beam 20 of a molecular precursor is directed onto a substrate 22 such that non-volatile species of the precursor's molecules are deposited on substrate. Generally, beam 20 includes a vapor of the precursor molecules mixed with in a carrier gas which moves at a supersonic velocity and which is preferably much lighter (e.g., at least 100 times lighter in terms of the respective atomic mass) than the precursor molecules. The amount of precursor molecules in beam 20 is typically significantly smaller than (e.g., about 10% of) the amount of carrier gas molecules so as to allow them to acquire the supersonic velocity of the gas carrier. Typically, the deposition is performed in vacuum conditions. Thus, in various exemplary embodiments of the invention substrate 22 is placed in a vacuum chamber 28 and beam 20 is generated in chamber 28 or being introduced into chamber 28 via a suitable beam inlet 18. A typical pressure in chamber 28 is below 10⁻⁴ bar or below 10⁻⁵ bar.

Beam 20 can be generated by a pulsed valve system generally shown at 24. System 24 can be placed in chamber 28 or it can be mounted withy respect to chamber 28 such that chamber 28 receives beam 20 through inlet 18.

Many types of pulsed valve systems are contemplated. Generally, any pulsed valve system that can generates sufficiently short pulses and can be heated to vaporize the precursor molecules (e.g., to 250° C.) can be used. Preferably, the pulsed valve system 24 is a digitally controlled system so as to allow better control on the properties, such as thickness, shape and pattern of the fabricated film.

Typically, but not necessarily, system 24 is operated such that the non-volatile species are deposited on substrate 22 at low rates. In some embodiments of the present invention the species are deposited at a rate of less than 0.01 atomic layers per pulse, but can be as high as 10 atomic layers per pulse depending on the temperature of the valve. The characteristic pulse rate of beam 20 is preferably high, e.g., at least 30 Hz or at least 50 Hz or at least 100 Hz or at least 500 Hz, e.g., 1,000 Hz or more. High pulse rates are particularly useful for low deposition rates of the molecules, since it allows both rapid and accurate deposition. Specifically, rapidness is facilitated by the high pulse rates and accuracy is facilitated by the low deposition rates. Further accuracy can be provided by selecting a beam with low divergence angle. Typically, but not necessarily, beam 20 is characterized by a beam divergence angle of less than 20°

A representative example of a pulsed valve system suitable for the present embodiments is described hereinunder. In some embodiments of the present invention pulsed valve system disclosed in Even et al., J. of Chem. Phys., 112, 18:8068-8071 (2000), the contents of which are hereby incorporated by reference, is used.

In various exemplary embodiments of the invention the beam is characterized by a kinetic energy per molecule which is at least 10 times the kinetic energy that the molecule would have had, had the molecule been a thermal molecule at a temperature of about 1000 degrees Kelvin. The kinetic energy of a thermal molecule is (3/2) kT, where k is the Boltzmann constant (approximately 86 microelectronvolts per kelvin) and T is the temperature of the molecule. For a thermal molecule, e.g., of an organic precursor, at a temperature of 1000K the kinetic energy of a molecule is about 0.086 eV. Thus, in various exemplary embodiments of the invention the beam is characterized by a kinetic energy of at least 1 eV per molecule or at least 5 eV per molecule or at least 6 eV per molecule or at least 7 eV per molecule or at least 8 eV per molecule or at least 9 eV per molecule or at least 10 eV per molecule or at least 11 eV per molecule or at least 12 eV per molecule or at least 13 eV per molecule or at least 14 eV per molecule, e.g., about 15 eV per molecule or more. These embodiments are unlike conventional CVD techniques in which the kinetic energy per molecule equals the thermal energy of the molecule at the temperatures of the CVD chamber (typically of the order of 1000K).

Optionally and preferably the beam is characterized by a pulse duration of less than 50 μs or less than 40 μs or less than 30 μs, e.g., 20 μs or less. Short pulse durations are useful to reduce the required pumping capacity in the system.

The non-volatile species typically comprise collision products which are produced when the molecules of the precursor collide with substrate 22. This is facilitated by the relatively high kinetic energy of the molecules which ensures an elevated probability for molecular dissociation upon collision. In some embodiments, the method proceeds to 12 at which the molecules are going through a dielectric barrier discharge volume and being dissociated prior to the deposition. In these embodiments, the non-volatile species comprise dissociation products which are produced during the discharge.

The discharge can be achieved by a gas discharge system 26 mounted on pulsed valve system 24 for receiving beam 20 and discharging the molecules so as to dissociate them into charged and/or neutral debris, e.g., stable, metastable atoms, molecular radicals or unstable ions. In various exemplary embodiments of the invention gas discharge system 26 comprises a dielectric barrier discharge (DBD) system. A representative example of a DBD system suitable for the present embodiments is described hereinunder.

The method ends at 13.

Before providing a further detailed description of the method and system of the present embodiments, attention will be given to the advantages and potential applications offered thereby.

The method and system of the present embodiments allows control of the film growth to unprecedented levels and can therefore facilitate fabrication of films with various properties, including, without limitation, abrupt and shallow semiconductor junctions, atomic layer deposition, directional deposition and activated precursor deposition. Such enhanced control can be achieved, for example, by providing an extremely small amount of gas at each pulse thereby allowing accurate pressure control. The method and system of the present embodiments are capable of increasing the kinetic energy of the molecules in the supersonic beam from about 0.1 ev to more than 10 ev in a controlled way by choosing the mass of the carrier gas. Such control can be used to select the dissociation rate and the character of the deposited film and/or its nanometric structure. The advantage of these embodiments is that it facilitates film growth at relatively low substrate temperature, hence reduce diffusion and allow growth of shallow or abrupt junctions. Preferably, the film is fabricated while the substrate is at a temperature of less than 140° C. or less than 130° C. or less than 120° C. or less than 110° C. or less than 100° C.

The ability of the present invention, in some embodiments thereof, to provide digital control of the number and rate of pulses allows for accurate and reproducible control over a wide range of growth rate, typically of the order of 1:1,000 or 1:10,000. This is advantageous over conventional technique in which the growth rate control of the rate does not exceed 1:100.

The film fabricated in accordance with some embodiments of the present invention can be used in a variety of applications.

For example, in some embodiments of the present invention the method and/or system is used for fabricating optical element, such as, but not limited to, a reflective optical element, an antireflective optical element, a transmissive optical element, a birefringent optical element, a polarizing optical element and the like. The method and/or system of the present embodiments can be used for fabricating, multilayer thin film structures, such as, but not limited to, thin film multilayer coatings that are infrared (IR) reflective and radiofrequency (RF) transparent, signature control films that are reflective only in particular bands of the infrared and are otherwise transmissive or absorptive, coatings for modifying the spectral emittance of a surface by changing its reflectance and absorbance, dichromatic color-shift coating compositions and the like.

The optical element or multilayer thin film structure of the present embodiments can serve as a component in many appliances. For example, an antireflective element, fabricated in accordance with some embodiments of the present invention can be placed at the outermost surfaces of a displays, such as a cathode-ray tube display, a plasma display panel (PDP), an electroluminescent display (ELD) and a liquid crystal display (LCD), for the purpose of preventing a contrast drop from occurring by reflections of outside light from the display surface and ambient-light reflection in image display apparatus.

The present embodiments can also be used as a technique for shielding unnecessary solar radiation, the optical thin film of the present embodiments can be used as, e.g., a blue red reflector (BRR) coating. This embodiment is particularly useful for reflecting ultraviolet and near-infrared lights so as to prevent excess thermal input and achieve lower temperature of, e.g., a solar cell. The film of present embodiments can additionally be used as coating for reducing angle-of-incidence dependent spectral response, in many applications, including, without limitation, optical sensors, head mounted display systems, spectacles or sunglasses and the like.

The film of present embodiments can further be used in laser systems wherein the internal walls of the optical cavity can be coated by the film to provide an optical resonator.

In some embodiments of the present invention a film fabricated by the method and/or system can be employed in a semiconductor device, including, without limitation, an electronic circuitry, a thin film transistor (TFT) array, or the like. For example, a TFT array can include a patterned semiconductor layer between two patterned metallic layers, wherein one or more of the layers is fabricated by the method and/or system of the present embodiments.

In some embodiments of the present invention a film fabricated by the method and/or system can be used as an interconnect element in an electronic circuitry such as an integrated circuit chip which may be formed by any of the conventional integrated circuit fabrication techniques. The film can include thin film pattern which is connected to regions within a semiconductor body optionally followed more levels of metallization.

The method and system of the present embodiments can also be used for generating a beam of atoms or ions. Such beam can be used for fabrication of a film, e.g., a thin film, on a substrate as further detailed hereinabove. Such beam can additionally be used for in research purposes, large scale generation of a particular type of atomic species (e.g., ozone), generation of, e.g., excimer UV light sources, clean environmental emission and surfaces and the like.

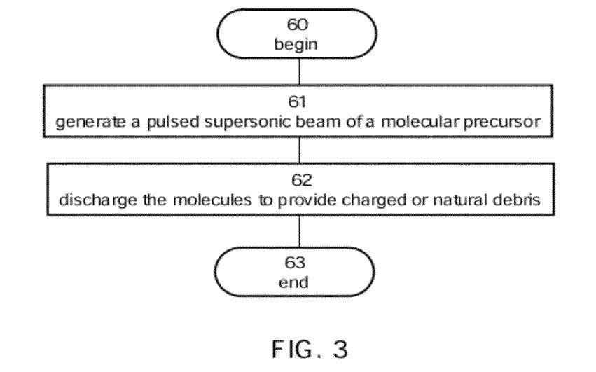

FIG. 3 is a schematic illustration of a method suitable for generating a beam of atoms or ions, according to various exemplary embodiments of the present invention. The method begins at 60 and continues to 61 at which a pulsed supersonic beam, e.g., beam 20 is generated. Beam 20 can be generated, for example, by pulsed valve system 24. The method continues to 62 at which molecules of the precursor are exposed to the discharge to dissociate the molecules into charged and/or neutral debris, e.g., stable, metastable or unstable ions or atoms. The discharge can be achieved by gas discharge system 26 which can be mounted on system 24 for receiving beam 20. Preferably, system 26 is a DBD system.

In various exemplary embodiments of the invention at least one of a pulse duration, a pulse rate, an amount of molecules per pulse, and a velocity profile of the molecules is selected such that a characteristic translational temperature of the produced atoms or ions is at most 1K.

The method ends at 63.

The molecular precursor is preferably selected in accordance with the application for which the thin film is fabricated. Preferably, the molecular precursor has a sufficiently high atomic mass such that the combination of supersonic velocity and high mass provides it with sufficiently high kinetic energy. This high kinetic energy is than used to dissociate the precursor upon impact with the substrate. Many types of molecular precursors are contemplated. Generally, any volatile precursor suitable for CVD and/or Metal Organic CVD (MOCVD) can be used. For example, the molecular precursor can include any of the III-V, II-VI compounds and allied semiconductors, such as ternary and quaternary compounds. In some embodiments of the present invention the molecular precursor is organic.

The molecular precursor can include a metal such iridium, ruthenium, rhenium, osmium, rhodium, platinum and gold. In some embodiments of the present invention molecular precursor comprises a metal carbonyl, such as, but not limited to, ruthenium carbonyl, rhenium carbonyl or other carbonyls, e.g., W(CO)₆, Mo(CO)₆, Co₂(CO)₈, Rh₄(CO)₁₂, Cr(CO)₆, and Os₃(CO)₁₂.

In some embodiments of the present invention the molecular precursor is a ruthenium-containing precursor, such as, but not limited to, the aforementioned ruthenium carbonyl, or a ruthenium organometallic precursor.

The gas carrier is, as stated, preferably lighter than the molecular precursor. Suitable gas carriers are, without limitation, helium, neon and argon. In some exemplary embodiments of the invention the gas carrier is helium and in some exemplary embodiments of the invention the gas carrier is a mixture of helium and neon, or any mixture of these gases. The supersonic velocity of the gas carrier depends on the operational parameters of pulsed valve system 24 and on the mass of the gas molecules.

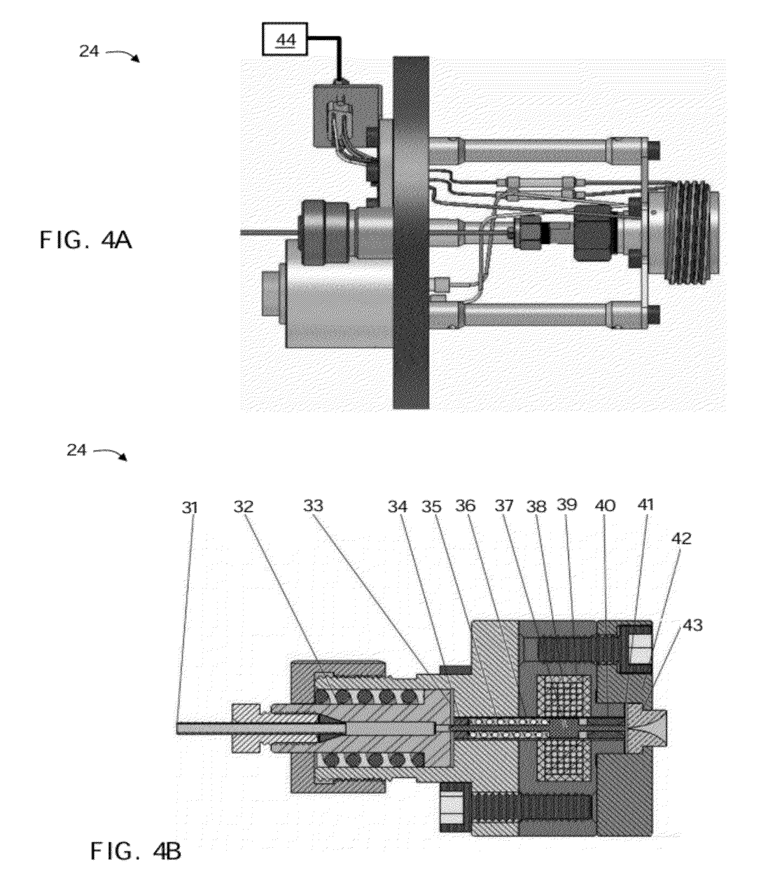

Reference is now made to FIGS. 4A and 4B which are schematic illustrations showing a perspective view (FIG. 4A) and a cross sectional view (FIG. 4B) of a pulsed valve system suitable to serve as pulsed valve system 24, according to some embodiments of the present invention. System 24 optionally comprises an inlet gas tube 31 which can be made, for example, from stainless alloy, and a nozzle 43 through which beam 20 (not shown) emerges. A typical diameter of tube 31 is about 1/16″. Nozzle 43 can be made of a ceramic material, such as, but not limited to, Zirconia, or hardened stainless steel. Connecting tube 31 and nozzle 43 is a pressure vessel 36 between two a guiding ferrules 34 and 40. Ferrules 34 and 40 and vessel 36 can be ceramic, e.g., Zirconia. Alternatively, vessel 36 can be made of a stainless alloy. Vessel 36 extends between the ferrules through a reciprocating plunger 37, which is typically made of a magnetic stainless steel alloy, and which is placed in an insulated (e.g., kapton insulated) copper coil 38. Coil 38 is enclosed in a magnetic shield and field concentrator 39, which can be, e.g., permendure.

At the rear part of system 24 there are a tightening spring and pressure relief valve 32. The spring typically applies a force of about 180N. At the middle part of system 24 there is return spring 35 which may be made, e.g., of a stainless alloy. Also shown are a rear 33 and a front 41 foil gaskets at the front and rear sides of vessel 36, and a front flange and system body 42. Body 42 can be made of copper, and gaskets 33 and 41 can be made of kapton. A typical thickness of Gaskets 33 and 41 is about 0.125 mm.

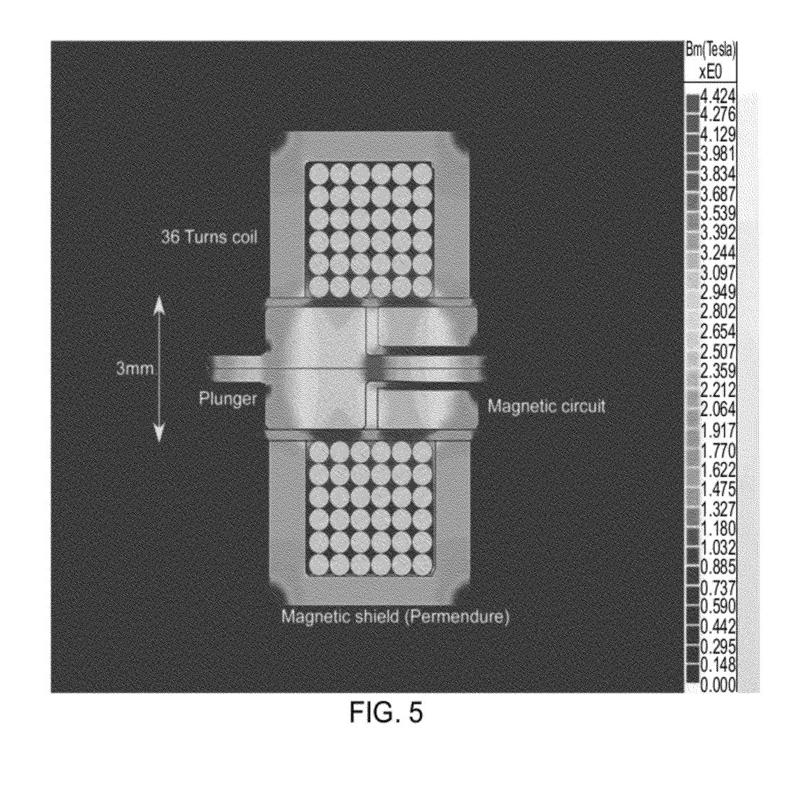

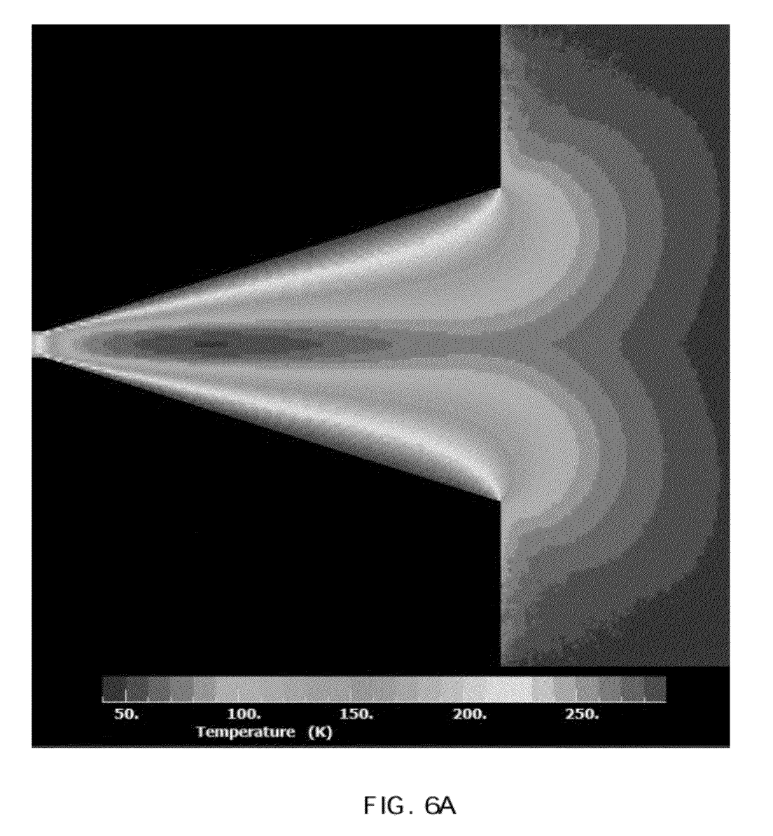

In use, inlet gas tube 31 is connected to a source of gas carrier (not shown), and a controller 44, preferably a digital controller, generates a high-current pulse (for example, about 30A) to induce at the center of the coil a magnetic field of high intensity (preferably of a few Teslas). A simulation of the generated magnetic field for a 36 turn coil is shown in FIG. 5.

Under the influence of the magnetic forces, reciprocating plunger 37 is displaced and returns to its sealing position by the spring 35. Typically, the plunger complete a return travel of about 0.01-0.1 mm within a duration of from about 10 μs to about 100 μs. The short opening time of the valve generated little gas load and low gas throughput. It was found by the present inventors that at operating pressure of 100 bar, repetition rate of 10 Hz and nozzle diameter of 0.2 mm, the gas throughput is approximately 0.01 L Torr/s. The short gas pulse generates a short packet of fast moving seeded gas.

Before reaching the nozzle, the gas carrier encounters the molecules of the precursor, which is typically maintained as a powder and vapor in thermodynamic equilibrium that is dependent on the valve's temperature. A small amount of precursor vapor is carried with the gas carrier into the nozzle. The carrier-gas, obtaining a supersonic velocity, accelerates the precursor molecules to approximately the same velocity as that of the unseeded carrier gas. The beam which now contains both the gas carrier and the precursor molecules emerges through the nozzle and begins to expand within a vacuum chamber (not shown). The pressure in the vacuum chamber can be less than 10⁻⁴ bar or less than 10⁻⁵ bar.

Nozzle 43 can have any shape characterized by a gradually increasing cross section outwardly flared shape, including, without limitation, a cone, a trumpet and the like. Preferably, the shape of cone 43 is selected such as to reduce the temperature of beam at the flared part of the nozzle.

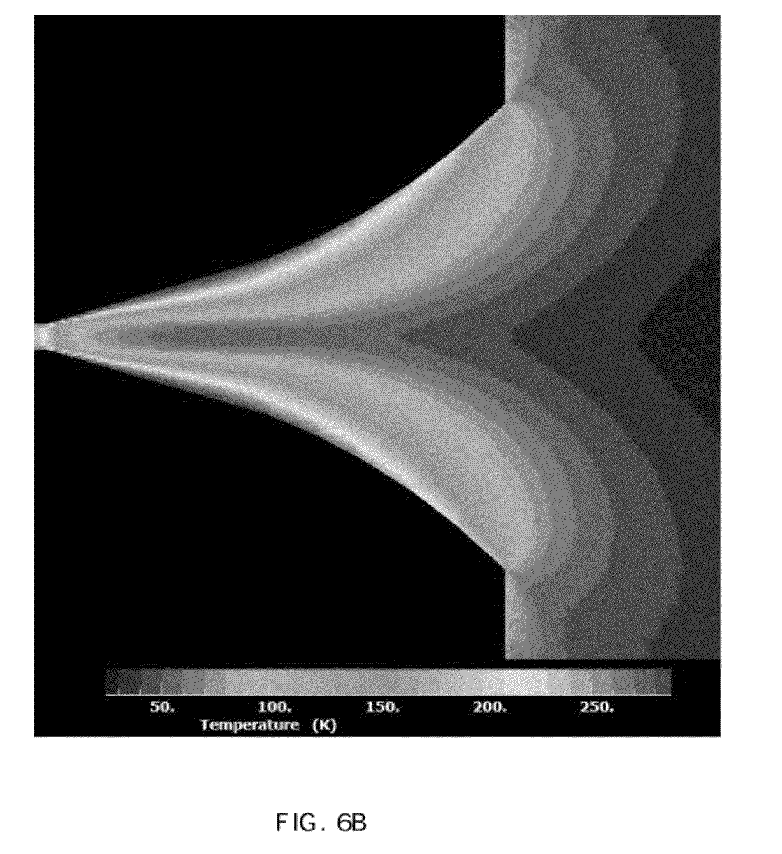

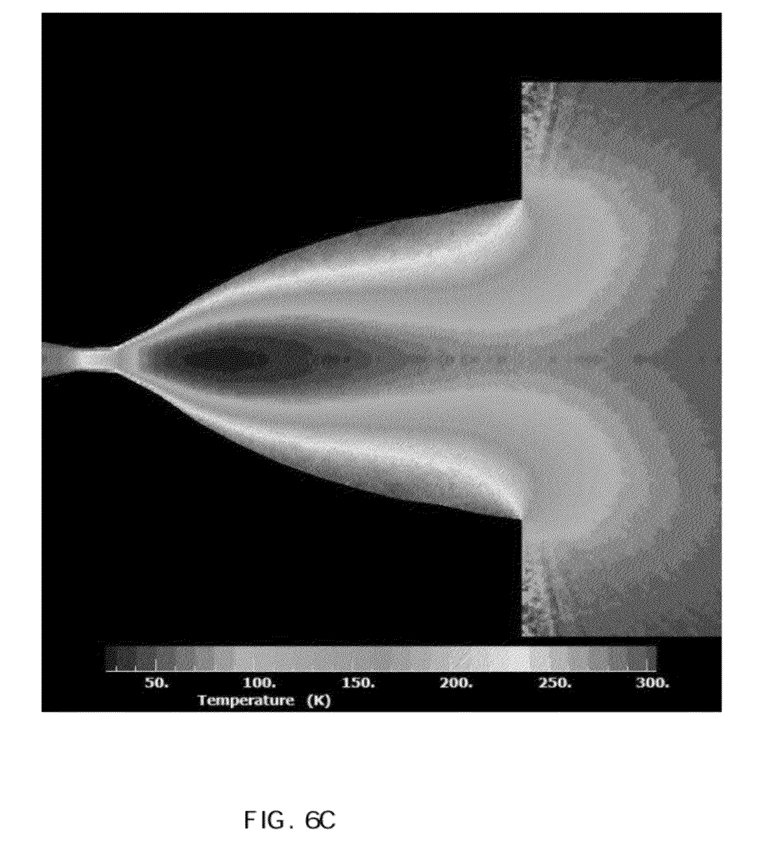

FIGS. 6A-C show temperature maps of a cone nozzle (FIG. 6A), a trumpet nozzle (FIG. 6B) and a bell-shape (Lavalle) nozzle (FIG. 6C). As shown, the temperature at the flared part of the nozzle is lower for the cone nozzle and the trumpet nozzle than for the bell-shape nozzle. Thus, in various exemplary embodiments of the invention nozzle 43 has a cone-like shape or a trumpet-like shape. Other shapes for the nozzle (including a bell shape) are not excluded from the scope of the present invention.

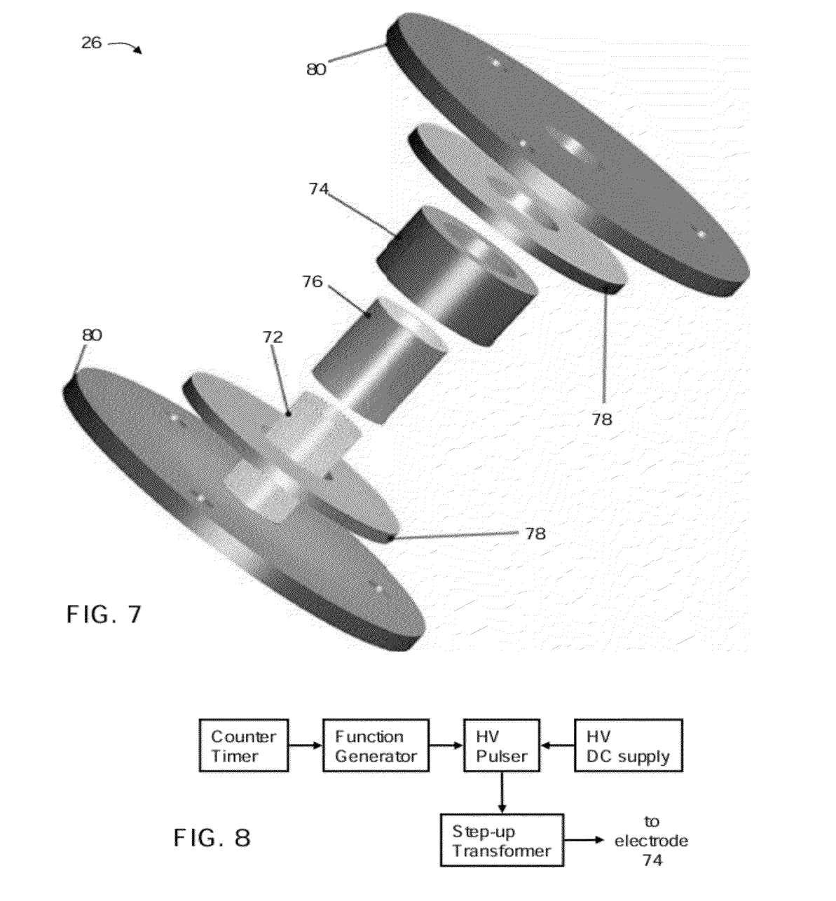

Reference is now made to FIG. 7 which is a schematic illustration showing an exploded view of a DBD system suitable to serve as gas discharge system 26, according to some embodiments of the present invention. System 26 comprises a pair of electrodes 72 and 74 made of electrically conductive materials, such as stainless steel or the like. In the illustration of FIG. 7, electrodes 72 and 74 are shown as two concentric cylindrical electrodes, but other electrode configurations are not excluded from the scope of the present invention.

Preferably, one of electrodes 72 and 74 is perforated. In the illustration of FIG. 7, inner electrode 72 is perforated and outer electrode 74 is not perforated, but an opposite configuration is also contemplated. Perforation can be selected to allow about 90% transmission.

One of the electrodes (e.g., electrode 72) is grounded while the other electrode is connected to a high voltage (e.g., at least 2 kV or at least 3 kV or at least 4 kV) power source (not shown). Preferably, the power source is configured to provide a pulsed voltage.

The sizes of the electrodes are compatible with the beam outlet of system 24 (namely the flared end of the nozzle). For example, when electrodes 72 and 74 are concentric and cylindrical, the inner diameter of electrode 72 are, about 5 mm and about 7 mm in length, and the typical dimensions for electrode 74 are about 6 mm in inner diameter, about 8 mm in outer diameter and about 7 mm in length.

System 26 further comprises a dielectric barrier 76 between electrodes 72 and 74. When the electrodes are cylindrical, dielectric barrier 76 is also cylindrical. Barrier 76 can be made of any dielectric material, including, without limitation, alumina. The thickness of barrier 76 is typically about 0.5 mm. In some embodiments of the present invention system 26 comprises one or more isolation elements 78 Two to complete the isolation from ground. Isolation elements 78 can be made of any ceramic material, such as macor® or the like. System 26 can be assembled between supporting elements 80, which can also be made of stainless steel.

In use, high AC voltage pulses are applied to the non-grounded electrode. A suitable electrical driver scheme for the discharge is illustrated in FIG. 8. A function generator can be used to create a burst of several logic level pulses, spaced at predetermined time-intervals. A typical time-interval between pulses is from about 0.001 second to about 1 second, depending on the pulse rate of the valve. The logic pulses are sent to a high voltage (e.g., 2 kV) pulser, and then to a step-up transformer for boosted the voltage, e.g., to 6 kV peak to peak. The transformer can be wound on a core. In experiments performed by the inventors of the present invention an “E” core ferrite was used.

It is expected that during the life of a patent maturing from this application many relevant gas discharge systems and pulsed valve systems will be developed and the scope of these terms is intended to include all such new technologies a priori.

As used herein the term “about” refers to ±10%.

The word “exemplary” is used herein to mean “serving as an example, instance or illustration.” Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments.” Any particular embodiment of the invention may include a plurality of “optional” features unless such features conflict.

The terms “comprises”, “comprising”, “includes”, “including”, “having” and their conjugates mean “including but not limited to”.

The term “consisting of means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

### Example 1

### Deposition of Ruthenium Thin-films

Following is a description of experiments in which embodiments of the present invention have been utilized for fabricating thin-films made of ruthenium.

### Methods

Embodiments of the present invention have been utilized for fabricating thin-films made of ruthenium.

The experimental setup included a pulsed valve system similar to the system described above with respect to FIGS. 4A-B including a valve controller, a turbomolecular pump (a Leybold Turbovac 361C, pumping speed 340 liter/sec), a rotary oil pump, a gas balloon, a pressure gauge for balloon, and vacuum gauge and temperature controllers for the substrate and valve temperatures.

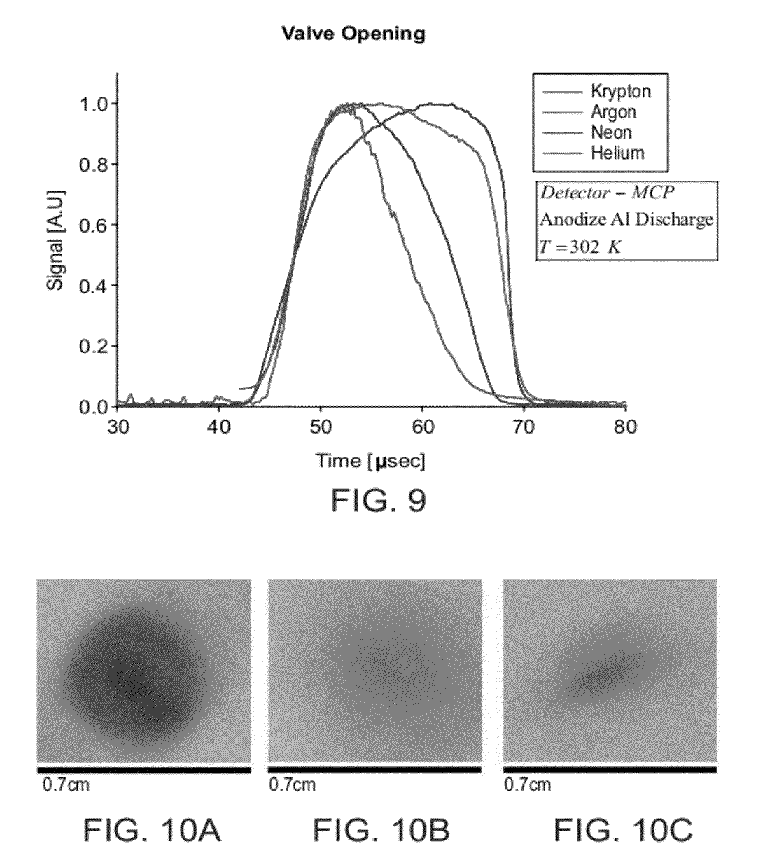

The pulsed valve opening as a function of time is shown in FIG. 9. In the present example, a quartz substrate was used, and was heated using a tungsten filament. The substrate was positioned at a distance of 5 cm from the nozzle.

Adiabatic supersonic expansion from high pressure of approximately 100 bar to high vacuum of approximately 10⁻⁵ to 10^{31 7} bar, occurred in a vacuum chamber. The turbomolecular pump was backed by a two stage rotary oil pump, which was configured to achieve an ultimate vacuum of 1.3×10⁻³ bar.

The pulsed valve system was operated at a stagnation pressure in the range of 40-60 bar, and the stagnation temperature was varied. The accuracy was 0.01K for temperature measurement and 0.1 bar for the pressure measurement. The valve was triggered at 30 Hz repetition rate and pulse duration of 32.5 μs to maintain a background pressure of no more than 10⁴ Ton in the vacuum chamber.

To obtain a thin film of ruthenium, the following protocol was employed:

(i) Ruthenium carbonyl precursor was placed in the pulsed valve system.

(ii) A gas bottle was filled with the desired gas (pure Helium or a Helium-Neon mixture at a pressure of 40-60 bar).

(iii) The chamber was pumped for a few hours to achieve high vacuum conditions.

(iv) The pulsed valve system was pulsed for about an hour to evacuate oxygen that remained in the tubes. This ensured that the tubes would be filled with the carrier-gas and that the precursor would not be oxidized.

(v) The pulsed valve was heated to 120° C. At this temperature, the vapor pressure of ruthenium carbonyl is approximately 0.1 mbars.

(vi) The substrate was heated to desired temperature (typically 100-200° C. degrees)

(v) The pulsed valve system was activated and vacuum pressure was monitored not to exceed 10⁻⁴ Torr.

### Results

FIGS. 10A-C are images showing the deposited layers of ruthenium. FIG. 10A shows the layers obtained using Helium carrier-gas at 125° C. substrate temperature, FIG. 10B shows the layers obtained using 15%-Neon-85%-Helium carrier gas at 150° C. substrate temperature, and FIG. 10C shows the layers obtained using 30%-Neon-70%-Helium carrier-gas at 200° C. substrate temperature.

Table 1 summarizes physical quantities characterizing the beam and deposition as calculated based on experimental measurements.

TABLE 1

| | | | | | Deposition Energy | |
|---|---|---|---|---|---|---|
| | | | | | | Kinetic Energy |
| | | | Kinetic Energy | | Thermal | per Degree of |
| | Atomic | Beam | of Ruthenium | Deposition | Energy of | Freedom for Ru- |
| Gas | Weight | Velocity | Carbonyl Vapor | Temperature | Substrate | thenium Carbonyl |
| Composition | (g/mol) | (m/s) | Ek (eV) | (K) | 3/2 kT (eV) | Vapor (eV) |
| 100% | 4.00 | 2020.18 | 13.52 | 398 | 0.051 | 0.173 |
| Helium | | | | | | |
| 15% Neon | 6.40 | 1597.09 | 8.45 | 423 | 0.055 | 0.108 |
| in Helium | | | | | | |
| 30% Neon | 8.80 | 1362.00 | 6.15 | 473 | 0.061 | 0.079 |
| in Helium | | | | | | |

The calculations presented in Table 1, were used to estimate the number of atoms colliding on the surface of the substrate. To this end, the calculation was based on the relation: E_{TOT}=Eₖ/d+(3/2)kTN, where Eₖ/d is the energy per degree of freedom, k is the Boltzmann constant, T is the temperature and N is the number of atoms with which the ruthenium carbonyl molecule collided on the quartz surface. Note that since ruthenium carbonyl contains 27 atoms it has d=27*3−3=78 degrees of freedom. The numerical values in Table 1 are were and the following values were obtained: E_{TOT}=1.055 eV, N=16.25.

Using crystallographic and chemistry data of Quartz substrate [CRC Handbook of Chemistry and Physics, Slebodnick et al. Inorganic Chemistry. 43 (2004) 5245-5252], and the estimated value of N, the number of molecular layers of quartz that were affected by the beam, was estimated to be from about 2 to about 7.

### Example 2

### Generation of Beams of Ions or Atoms

Following is a description of experiments in which embodiments of the present invention have been utilized for generating beams of ions or atoms.

### Methods

The experimental setup included a pulsed valve system similar to the system described above with respect to FIGS. 4A-B employing a trumpet shaped nozzle, and a DBD system similar to the system described above with respect to FIG. 7.

The discharge occurred between two concentric cylindrical electrodes. The inner grounded electrode (diameter of 5 mm and length of 7 mm) was made from perforated stainless steel foil (0.1 mm in thickness, and 90% transmission), the dielectric barrier between the electrodes was a thin alumina tubing (wall thickness of 0.5 mm), and the outer electrode was a cylinder (inner diameter of 6 mm, outer diameter of 8 mm). The outer electrode was pulsed at voltage of 4 kV.

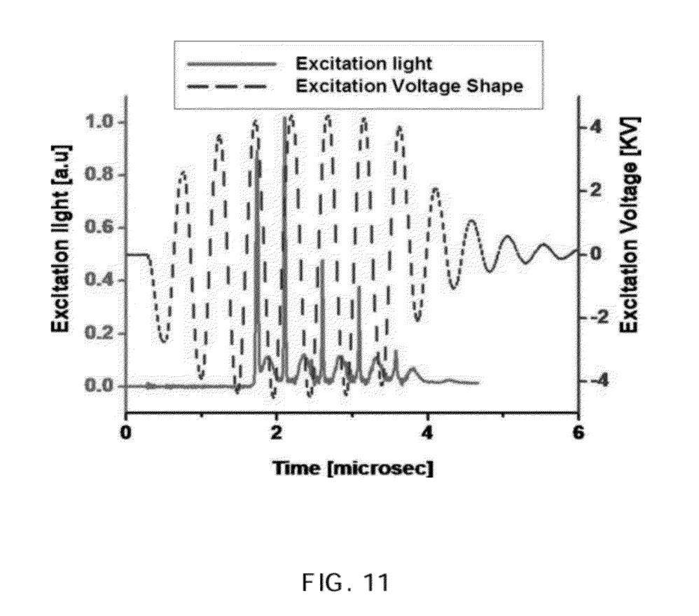

A function generator was used to create a burst of eight square logic level pulses, spaced at 0.6 s. The logic pulses were sent to a 2 kV voltage pulser, and then to a home-built step-up transformer, wound on an “E” core ferrite that boosted the voltage to 6 kV. The resulting rf burst and the light emitted as a result of the discharge pulses are shown in FIG. 11. The sharp (less than 20 ns) current spikes cause short duration bursts of light, demonstrating a self-limiting feature for the current flow.

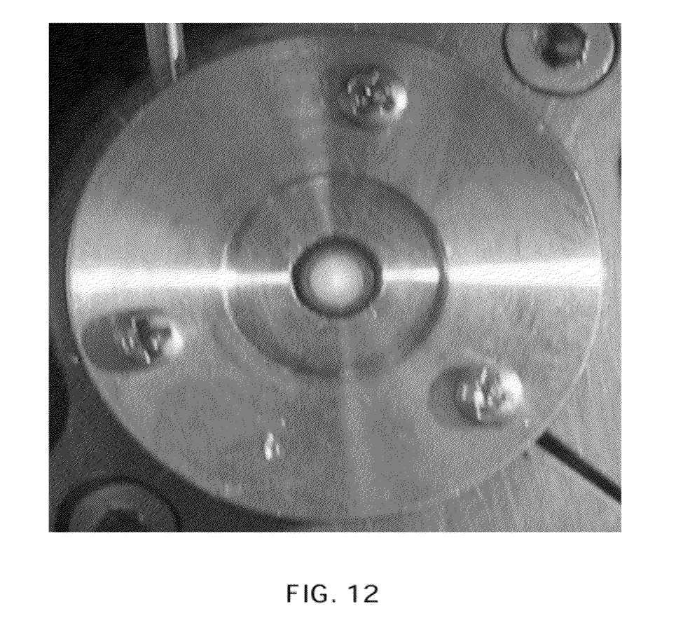

The uniformity of the volume excitation and the lack of hot spots that are found in conventional exposed electrode discharges is shown in FIG. 12. Based on the voltage drop (20 V) from the 170 nF capacitor bank supplying the current during the discharge, and pulse duration of 20 ns from the emitted light pulse, the current spikes were estimated to be about 300 A peak. The estimated pulse energy is 2 mJ with a peak power of about 100 kW. The coaxial geometry of the discharge electrodes and the self-limiting barrier discharge ensured a low impedance source to enable high intensity and short duration pulses. The system was operated for many days without any detected signs of sputtering on surfaces of the discharge volume or degradation in its operation.

The system was operated in a two chambers differentially pumped vacuum system separated by a skimmer. The chambers were pumped with a 300 l/s and 500 l/s turbo-pumps, respectively. When the valve operated at a repetition rate of 10 Hz the average pressure in the chambers was 2×10⁻⁵ and 2×10⁻⁶ mbar respectively (background pressure was negligible accounting for less than 1% of the pressure). This allowed estimating the number of atoms released by the valve in each pulse (about 10¹⁵ atoms in a 20 microsecond pulse). A three millimeter diameter skimmer, placed 120 mm from the valve, transmitted about 10¹³ atoms per pulse. The high transmission reflects the collimated beam shape from the trumpet shaped nozzle. The second chamber was equipped with an electron impact, axial, Time-Of-Flight (TOF) mass spectrometer [U. Even and B. Dick, Rev. Sci. Instrum. 71, 4415 2000], that allowed detecting fragmented molecular species generated in the DBD source. Deflection plates placed between the skimmer and the mass spectrometer allowed only neutrals to continue their way into the mass spectrometer. The DBD source generated Metastable atoms, Ions and fragmented neutrals in copious quantity. Since the electron impact in the mass spectrometer generates fragmented molecular species too, this contribution was subtracted from the mass spectrometer signal generated by the added DBD source to obtain the source discharge contribution itself.

### Results

### Excited Meta-Stable Atoms

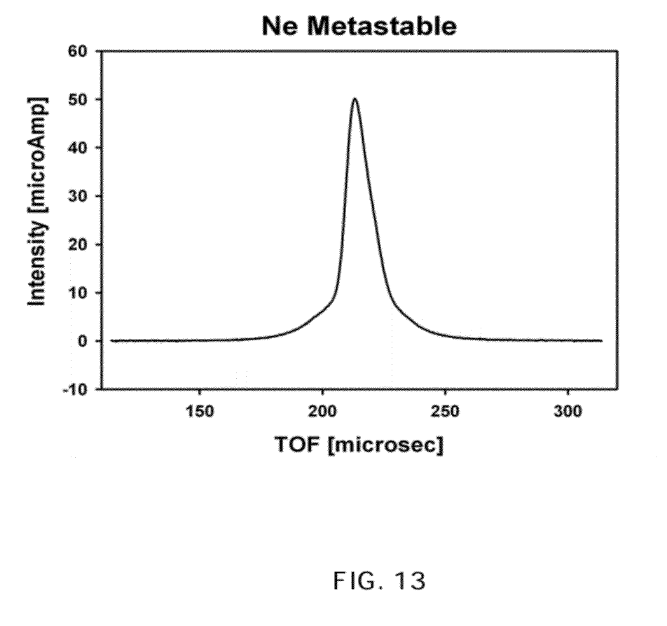

Electrostatic deflection was used to divert the charged species generated in the DBD discharge while a negatively biased plate collector was placed after the skimmer to register the electrons emitted when a metastable atom hit the plate. A current amplifier was used to record the current pulse shape as is depicted in FIG. 13.

Integrating the current over the pulse time allowed the estimation of the total charge emitted from the plate. Assuming one electron emitted per incoming excited atom resulted in the total number of 6.1×10⁹ atoms per valve pulse. It is emphasized that the collector plate was placed after the skimmer (skimmer valve distance was 120 mm) and represents only 1% of the total gas beam. The meta stable excitation fraction was estimated to be about 6×10⁻⁴ of the beam.

The arrival time and pulse width allow the estimation of the gas heating (about 8° C. above the valve temperature) and the Mach number (larger than 50).

### Charged Clusters Ions

A mixture of 1% Ammonia in Neon at a pressure of 50 bars was expanded from the valve. The discharge was timed to maximum cluster ions production. The ions generated at the valve exit by the discharge were skimmed, accelerated and entered a one meter long TOF tube. The mass separated ions were focused on a collector plate to measure the ion current with a limited time (and mass) resolution.

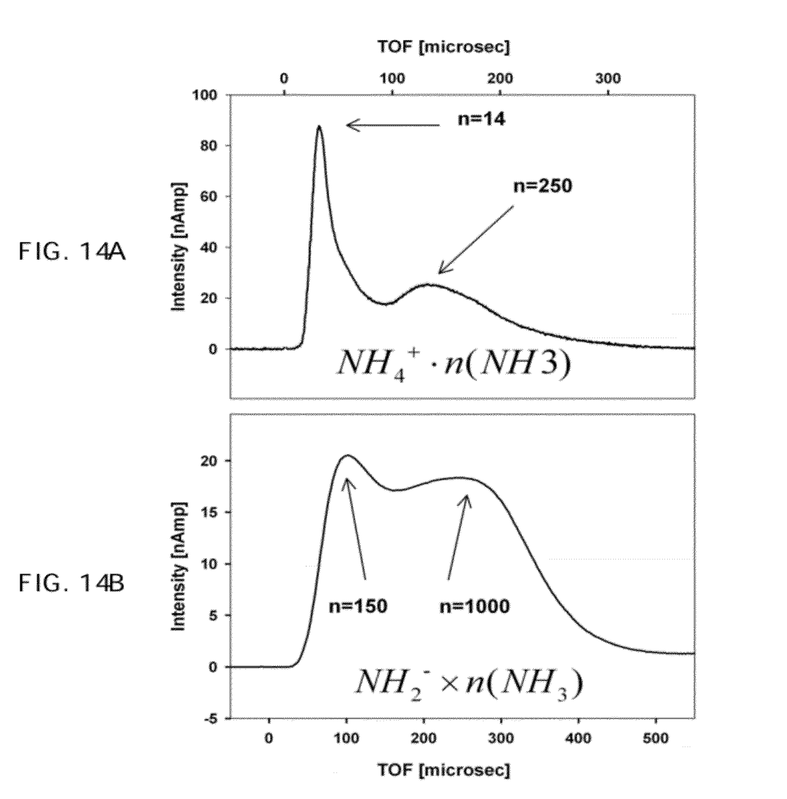

The positive and negative ion currents are presented in FIGS. 14A and 14B. The total number of positive ions per pulse was about 9.3×10⁷ and for negative ions was about 6.3×10⁷. As shown, the negative cluster ions contained much larger clusters that were not fragmented by the DBD discharge, presumably due to the presence of a large number of low energy electrons that attached themselves softly to the large clusters. The positive ion mass spectrum showed a similar bimodal mass distribution but with the smaller fragments dominating, evidence of extensive fragmentation due to the higher energy electrons required for ionization. The ions move with the neutral gas velocity and show similar Mach numbers (larger than 30).

### Neutral Atomic Fragments and Molecular Radicals

1% gas mixtures in Neon (O₂; N₂; CO,CO₂ and NH₃) were used. The gas was skimmed and passed through the TOF mass spectrometer, equipped with a hot filament electron impact ionizer. The electron impact causes dissociation of the molecules so both, say O and O₂ mass peaks are evident. When the DBD discharge was operated (after deflecting out the ions that were generated in the discharge) there was an addition to the O mass peak relative to the O₂ mass peak. This added signals are attributed to neutral O atoms generated by the discharge. The results are summarized in Table 2, below.

TABLE 2

| | Without | With | Discharge |
|---|---|---|---|
| | DBD (%) | DBD (%) | Contribution (%) |
| O/O₂ | 10.76 | 19.41 | 8.65 |
| N/N₂ | 7.11 | 9.13 | 2.02 |
| O/CO | 3.88 | 4.65 | 0.77 |
| C/CO₂ | 5.41 | 5.50 | 0.09 |
| O/CO₂ | 8.52 | 8.74 | 0.22 |
| CO/CO₂ | 15.46 | 19.12 | 3.66 |
| N/NH₃ | 1.52 | 2.62 | 1.10 |
| NH/NH₃ | 7.36 | 8.68 | 1.31 |

The collision with the predominant metastable carrier gas atoms transfers enough energy to cause molecular dissociation and several percent of the molecules are dissociated. The atomic fragments move with the same velocity and Mach numbers as the neutral beam.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1. A method of fabricating a film, comprising directing onto a substrate a pulsed supersonic beam of a molecular precursor characterized by kinetic energy of at least 1 eV per molecule, such that non-volatile species of molecules of said precursor are deposited on said substrate.

2. The method according to claim 1, wherein said beam is characterized by a pulse duration of less than 50 microseconds.

3. The method according to claim 1, wherein said non-volatile species comprise collision products being produced when said molecules collide with said substrate.

4. The method according to claim 1, further comprising exposing said molecules to a discharge prior to said deposition, wherein said non-volatile species comprise dissociation products being produced during said discharge.

5. The method according to claim 1, wherein said discharge is by a dielectric barrier discharge system.

6. The method according to claim 1, wherein said non-volatile species are deposited at a rate of less than 50 atoms in height per pulse.

7. The method according to claim 1, wherein said beam is characterized by a divergence angle of less than 20°.

8. The method according to claim 1, wherein said beam is characterized by a pulse rate of at least 30 Hz.

9. The method according to claim 1, further comprising using a digital controller for controlling a number of pulses in said pulsed supersonic beam.

10. The method according to claim 1, wherein said substrate is at a temperature of less than 140° C.

11. The method according to claim 1, wherein said precursor comprises a metal selected from the group consisting of iridium, ruthenium, rhenium, osmium, rhodium, platinum and gold.

12. The method according to claim 1, wherein said precursor comprises a metal carbonyl.

13. The method according to claim 1, wherein said beam comprises gas carrier which comprises at least one of helium, neon and argon.

14. A film fabricated by a method according to claim 1.

15. A reflective optical element, comprising the film of claim 14.

16. A solar cell, comprising the film of claim 14.

17. A transmissive optical element, comprising the film of claim 14.

18. A birefringent optical element, comprising the film of claim 14.

19. A polarizing optical element, comprising the film of claim 14:

20. A semiconductor device, comprising the film of claim 14.

21. An electronic circuitry, comprising the film of claim 14.

22. A thin film transistor array, comprising the film of claim 14.

23. A method of generating a beam of atoms or ions, comprising:
generating a pulsed beam which comprises a supersonic gas carrier mixed with a molecular precursor; and
exposing said beam to a discharge so as to dissociate molecules of said precursor into ions or atoms.

24. The method according to claim 23, wherein said beam is characterized by kinetic energy of at least 1 eV per molecule.

25. The method according to claim 23, wherein said beam is characterized by a pulse duration of less than 50 microseconds.

26. The method according to claim 23, wherein said discharge is by a dielectric barrier discharge system.

27. The method according to claim 23, wherein said beam comprises less than 50 molecular layers per pulse.

28. The method according to claim 23, wherein said beam is characterized by a divergence angle of less than 20°.

29. The method according to claim 23, wherein said beam is characterized by a pulse rate of at least 30 Hz.

30. The method according to claim 23, further comprising using a digital controller for controlling a number of pulses in said pulsed supersonic beam.

31. The method according to claim 23, wherein at least one of a pulse duration, a pulse rate, an amount of molecules per pulse, and a velocity profile of said molecules is selected such that a characteristic translation temperature of said atoms or ions is at most 1K.

32. A system for generating a beam of atoms or ions, comprising:
a pulsed valve system for generating a pulsed beam which comprises a supersonic gas carrier mixed with a molecular precursor; and
a gas discharge system mounted on said pulsed valve system for receiving and discharging said beam to dissociate molecules of said precursor into ions or atoms.

33. The system according to claim 32, wherein said pulsed valve system is configured to generate a beam characterized by a pulse duration of less than 50 microseconds and kinetic energy of at least 1 eV per molecule.

34. The system according to claim 32, wherein said gas discharge system comprises a dielectric barrier discharge system.

35. The system according to claim 32, wherein said beam comprises less than 50 molecular layers per pulse.

36. The system according to claim 32, wherein said beam is characterized by a divergence angle of less than 20°.

37. The system according to claim 32, wherein said beam is characterized by a pulse rate of at least 30 Hz.

38. The system according to claim 32, further comprising a digital controller for controlling a number of pulses in said pulsed supersonic beam.

39. The system according to claim 32, wherein at least one of a pulse duration, a pulse rate, an amount of molecules per pulse, and a velocity profile of said molecules is selected such that a characteristic translation temperature of said atoms or ions is at most 1K.
